(19) United States
(12) Patent Application Publication
(10) Pub. No.: US 2025/0150037 A1
(43) Pub. Date: May 8, 2025

(54) DUAL-OUTPUT AMPLIFIER CIRCUIT

(71) Applicant: Analog Devices, Inc., Wilmington, MA (US)

(72) Inventors: Wei Wang, Colorado Springs, CO (US); Michael E. Harrell, Colorado Springs, CO (US); Thomas A. Spargo, Colorado Springs, CO (US); Angel Rael, Colorado Springs, CO (US)

(21) Appl. No.: 18/504,753

(22) Filed: Nov. 8, 2023

(51) Int. Cl. H03F 1/02; H03F 1/52; H03F 3/193; H03F 3/60

(52) U.S. Cl. CPC H03F 1/0233; H03F 1/526; H03F 3/607; H03F 3/193; H03F 2200/151; H03F 2200/153; H03F 2200/45

(57) ABSTRACT

A capacitive load, an inductive load, or a transmission line coupled to an output of a closed-loop amplifier circuit can cause undesirable oscillations in a feedback signal of the amplifier circuit. The oscillations in the feedback signal can cause the amplifier circuit to exhibit instability and unpredictable behavior. Techniques are described that allow an amplifier circuit to provide a stable response while driving a capacitive load.

### FIELD OF THE DISCLOSURE

This document pertains generally, but not by way of limitation, to amplifier circuits.

### BACKGROUND

Electronic amplifier circuits are fundamental components in modern electronics and play an important role in enhancing weak electrical signals to desired levels. Amplifier circuits are widely used in various applications, including audio systems, telecommunication devices, medical equipment, and scientific instruments. These circuits serve as building blocks for signal processing, enabling efficient transmission, amplification, and control of electrical signals in a wide range of systems.

Amplifier circuits are designed to increase the power, voltage, or current of an input signal while maintaining its integrity and fidelity. They are typically composed of active devices such as transistors or operational amplifiers (op-amps) and passive components like resistors, capacitors, and inductors. The active devices provide the necessary gain and control, while the passive components shape and control the signal characteristics.

Transistor-based amplifier circuits are commonly used due to their high gain, low noise, and broad frequency response. Bipolar junction transistors (BJTs) and field-effect transistors (FETs) are the most prevalent types employed in amplifier designs. BJTs offer excellent linearity and are often used in audio amplifiers, while FETs are preferred in applications requiring high input impedance and low power consumption, such as in radio frequency (RF) amplifiers.

### SUMMARY OF THE DISCLOSURE

This disclosure describes various techniques that allow an amplifier circuit to provide a stable response while driving a capacitive load or a transmission line.

In some aspects, this disclosure is directed to a dual-output amplifier circuit having a first output node and a second output node, the dual-output amplifier circuit comprising: a gain stage circuit having a non-inverting input node and an inverting input node, wherein the non-inverting input node is configured to receive an input voltage; a first buffer circuit coupled with the gain stage circuit, wherein an input node of the first buffer circuit is coupled with an output node of the gain stage circuit and is configured to receive an output voltage of the gain stage circuit, and wherein the first buffer circuit is configured to generate a first output voltage at the first output node; a first resistive network coupled between the first output node of the first buffer circuit and the inverting input node of the gain stage circuit, wherein the first resistive network has a first resistance; a second buffer circuit coupled with the first buffer circuit, wherein an input node of the second buffer circuit is coupled with the output node of the gain stage circuit and is configured to receive the output voltage of the gain stage circuit, and wherein the second buffer circuit is configured to generate a second output voltage at the second output node; and a second resistive network coupled between the second output node of the second buffer circuit and a reference node, wherein the second resistive network has a second resistance proportional to the first resistance, wherein the second output voltage is equal to the first output voltage.

In some aspects, this disclosure is directed to a dual-output amplifier circuit having a first output node and a second output node, the dual-output amplifier circuit comprising: a gain stage circuit having a non-inverting input node and an inverting input node, wherein the non-inverting input node is configured to receive an input voltage; a first buffer circuit coupled with the gain stage circuit, wherein an input node of the first buffer circuit is coupled with an output node of the gain stage circuit and is configured to receive an output voltage of the gain stage circuit, and wherein the first buffer circuit is configured to generate a first output voltage at the first output node; a first resistive network coupled between the first output node of the first buffer circuit and the inverting input node of the gain stage circuit, wherein the first resistive network has a first resistance; a second buffer circuit coupled with the first buffer circuit, wherein an input node of the second buffer circuit is coupled with the output node of the gain stage circuit and is configured to receive the output voltage of the gain stage circuit, and wherein the second buffer circuit is configured to generate a second output voltage at the second output node; and a second resistive network coupled between the second output node of the second buffer circuit and a reference node, wherein the second resistive network has a second resistance proportional to the first resistance, wherein the second output voltage is equal to the first output voltage; and a third buffer circuit coupled in parallel with the second buffer circuit, wherein the third buffer circuit is coupled with the first buffer circuit, wherein an input node of the third buffer circuit is coupled with the output node of the gain stage circuit and is configured to receive the output voltage of the gain stage circuit, and wherein the third buffer circuit is configured to generate a portion of the second output voltage at the second output node.

In some aspects, this disclosure is directed to a dual-output amplifier circuit having a first output node and a second output node, the dual-output amplifier circuit comprising: a gain stage circuit having a non-inverting input node and an inverting input node, wherein the non-inverting input node is configured to receive an input voltage; a first buffer circuit coupled with the gain stage circuit, wherein an input node of the first buffer circuit is coupled with an output node of the gain stage circuit and is configured to receive an output voltage of the gain stage circuit, and wherein the first buffer circuit is configured to generate a first output voltage at the first output node; a first resistive network coupled between the first output node of the first buffer circuit and the inverting input node of the gain stage circuit, wherein the first resistive network has a first resistance; a second buffer circuit coupled with the first buffer circuit, wherein an input node of the second buffer circuit is coupled with the output node of the gain stage circuit and is configured to receive the output voltage of the gain stage circuit, and wherein the second buffer circuit is configured to generate a second output voltage at the second output node; and a second resistive network coupled between the second output node of the second buffer circuit and a reference node, wherein the second resistive network has a second resistance proportional to the first resistance, wherein the second output voltage is equal to the first output voltage; a third buffer circuit coupled in parallel with the second buffer circuit, wherein the third buffer circuit is coupled with the first buffer circuit, wherein an input node of the third buffer circuit is coupled with the output node of the gain stage circuit and is configured to receive the output voltage of the gain stage circuit, and wherein the third buffer circuit is configured to generate a portion of the second output voltage at the second output node; and a third resistive network configured to adjust a level of the second output voltage.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 is an example of an approach to a dual-output amplifier circuit.

FIG. 2 is an example of an approach to a dual-output amplifier circuit in accordance with various techniques this disclosure.

FIG. 3 is another example of an approach to a dual-output amplifier circuit in accordance with various techniques this disclosure.

### DETAILED DESCRIPTION

A capacitive load, an inductive load, or a transmission line coupled to an output of a closed-loop amplifier circuit can cause undesirable oscillations in a feedback signal of the amplifier circuit. The oscillations in the feedback signal can cause the amplifier circuit to exhibit instability and unpredictable behavior. This disclosure describes various techniques that allow an amplifier circuit to provide a stable response while driving a capacitive load.

FIG. 1 is an example of an approach to a dual-output amplifier circuit. The dual-output amplifier circuit 100 of FIG. 1 includes a gain stage circuit 102 having a non-inverting input node 104 configured to receive an input voltage Vin and an inverting input node 106. The gain stage circuit 102 generates an output voltage Vx at an output node 108.

An input node 110 of a first buffer circuit 112 is coupled with the output node 108 of the gain stage circuit 102. The input node 110 is configured to receive the output voltage Vx of the gain stage circuit 102, and the first buffer circuit 112 is configured to generate a first output voltage Vclose at a first output node 114. The first buffer circuit 112 sources current to a resistive network that includes resistive elements RA and RB. The resistive network can be arranged in a voltage divider configuration such that a voltage VDIV at node 144 is generated and fed back to the inverting input node 106. In some examples, the dual-output amplifier circuit 100 can include a resistive element RC coupled between a reference voltage and the inverting input node 106, such as to provide offset voltage.

In the example shown, the first buffer circuit 112 is arranged in a diamond buffer configuration, such as a diamond source follower, and includes a top portion 116 and a bottom portion 118. The top portion 116 includes a p-type field-effect transistor (FET) MP1A, an n-type FET MN1B, and a current source 120. A gate terminal of MP1A is coupled with the output node 108 of the gain stage circuit 102. A source terminal of MP1A is coupled with a gate terminal of MN1B and the current source 120. A drain terminal of MP1A is coupled with a reference node 126. A drain terminal of MN1B is coupled with a positive supply voltage VDC.

The bottom portion 118 includes an n-type FET MN1A, a p-type FET MP1B, and a current source 124. A gate terminal of MN1A is coupled with the output node 108 of the gain stage circuit 102. A source terminal of MN1A is coupled with a gate terminal of MP1B and the current source 124. A drain terminal of MN1A is coupled with a reference node 128. A drain terminal of MP1B is coupled with a reference node 130.

Because the threshold voltage VGS of a p-type FET is generally different from the threshold voltage VGS of an n-type FET and the temperature coefficient of the n-type FET and p-type FET are different, the first output voltage Vclose is not equal to the output voltage Vx of the gain stage circuit 102. For example, in FIG. 1, between the output node 108 of the gain stage circuit 102 and the first output node 114, there is an increase in one VGS and a decrease in one VGS, via the top portion 116, or a decrease in one VGS and an increase in one VGS, via the bottom portion 118. But, because the transistors MP1A and MN1B are different types and the transistors MN1A and MP1B are different types, the first output voltage Vclose will likely not be the same as the output voltage Vx.

The dual-output amplifier circuit 100 includes a second buffer circuit 132. An input node 134 of the second buffer circuit 132 is coupled with the first output node 114 of the first buffer circuit 112. In the example shown, the second buffer circuit 132 is arranged in a diamond buffer configuration, such as a diamond source follower, and includes top portion 136 and bottom portion 138. The top portion 136 includes a p-type FET MP2A, an n-type FET MN2B, and a current source 140. The bottom portion 138 includes an n-type FET MN2A, a p-type FET MP2B, and a current source 142. The top portion 136 and the bottom portion 138 of the second buffer circuit 132 are arranged in a manner similar to the top portion 116 and the bottom portion 118 of the first buffer circuit 112 and, for brevity will not be described in detail again. The second buffer circuit 132 generates an output voltage Vopen for the dual-output amplifier circuit 100 at an output node 122.

For conventional amplifiers, the output voltage Vclose is used to drive external loads. Heavy capacitive loads or transmission lines can make the output voltage Vclose oscillate and eventually bring the closed loop of the gain stage circuit 102, the first buffer circuit 112 and the resistive network unstable.

The dual output node amplifier has two output nodes: the first output node 114 which produces a voltage Vclose and the output node 122 which produces a voltage Vopen. The voltage Vopen is the duplicate voltage of Vclose, which is the amplified signal of Vin. Vopen is used to drive external load, while it does not feedback to the closed-loop, so that the closed loop is always stable.

To do so, the voltage Vclose should equal the voltage Vopen. However, there are three factors that make the voltage Vclose and the voltage Vopen unequal. First, as mentioned above, the threshold voltage VGS of a p-type FET is generally different from the threshold voltage VGS of an n-type FET and are also temperature dependent. Second, there is extra current flowing the resistive network including resistive elements RA and RB and, as such, the DC bias point of the first buffer circuit 112 is different from that of the second buffer circuit 132. Third, the first buffer circuit 112 and the second buffer circuit 132 do not share the same input voltage: Vx, the input voltage of first buffer circuit 112, and Vclose, the input voltage of the second buffer circuit 132, are different voltages.

As described below, by using the techniques of this disclosure, the output voltage Vx at output node 108 of the gain stage circuit 102 can be applied to both the first buffer circuit 112 and the second buffer circuit 132.

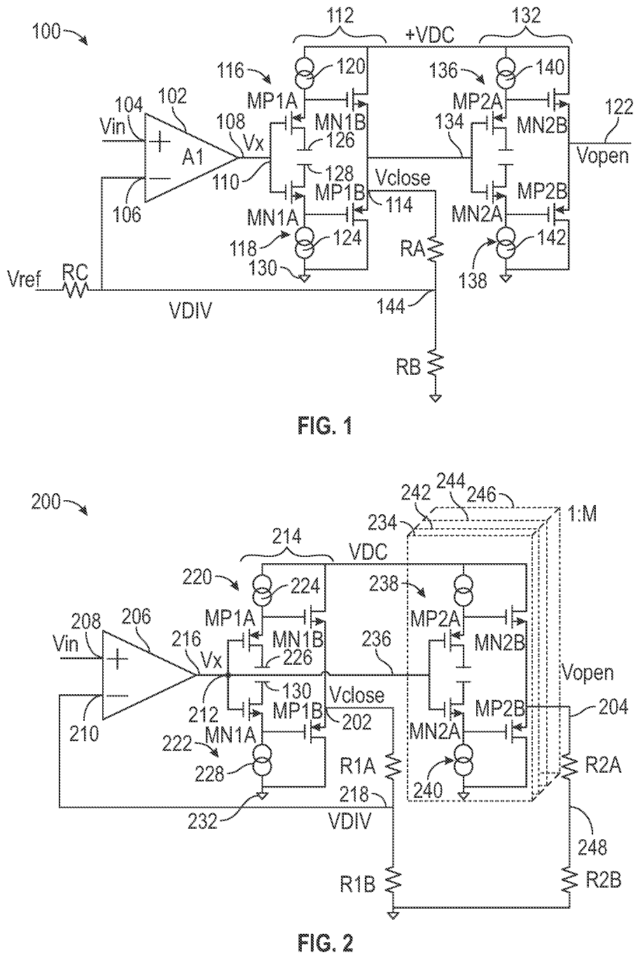

FIG. 2 is an example of an approach to a dual-output amplifier circuit in accordance with various techniques this disclosure. The dual-output amplifier circuit 200 of FIG. 2 has a first output node 202 and a second output node 204. As described in detail below, the two buffer circuits of the dual-output amplifier circuit 200 have the same bias condition and, as such, the output voltage Vopen of the dual-output amplifier circuit 200 equals the voltage Vclose.

The dual-output amplifier circuit 200 includes a gain stage circuit 206 having a non-inverting input node 208 and an inverting input node 210, where the non-inverting input node 208 is configured to receive an input voltage Vin. An input node 212 of a first buffer circuit 214 is coupled with the output node 216 of the gain stage circuit 206. The input node 212 is configured to receive the output voltage Vx of the gain stage circuit 206, and the first buffer circuit 214 is configured to generate a first output voltage Vclose at the first output node 202.

The first buffer circuit 214 sources current to a first resistive network that includes resistive elements R1A and R1B, where the resistive element R1B is coupled to a reference node. The first resistive network is coupled between the first output node of the first buffer circuit and the inverting input node of the gain stage circuit, where the first resistive network has a first resistance. The first resistive network can be arranged in a voltage divider configuration such that a voltage VDIV at node 218 is generated and fed back to the inverting input node 210.

In the example shown, the first buffer circuit 214 is arranged in a unity gain configuration, such as a diamond buffer configuration, e.g., a diamond source follower, and includes a top portion 220 and a bottom portion 222. The top portion 220 includes a p-type FET MP1A, an n-type FET MN1B, and a current source 224. A gate terminal of MP1A is coupled with the output node 216 of the gain stage circuit 206. A source terminal of MP1A is coupled with a gate terminal of MN1B and the current source 224. A drain terminal of MP1A is coupled with a reference node 226. A drain terminal of MN1B is coupled with a positive supply voltage VDC.

The bottom portion 222 includes an n-type FET MN1A, a p-type FET MP1B, and a current source 228. A gate terminal of MN1A is coupled with the output node 216 of the gain stage circuit 206. A source terminal of MN1A is coupled with a gate terminal of MP1B and the current source 228. A drain terminal of MN1A is coupled with a reference node 230. A drain terminal of MP1B is coupled with a reference node 232.

The dual-output amplifier circuit 200 includes a second buffer circuit 234 coupled with the first buffer circuit 214. In contrast to the dual-output amplifier circuit 100 of FIG. 1, an input node 236 of the second buffer circuit 234 is coupled with the output node 216 of the gain stage circuit 206 and is configured to receive the output voltage Vx of the gain stage circuit 206, and the second buffer circuit 234 is configured to generate a second output voltage Vopen at the second output node 204. That is, in contrast to FIG. 1 in which the input node of the second buffer circuit receives the output voltage Vclose of the first buffer circuit, each buffer circuit of dual-output amplifier circuit 200 receives the output voltage Vx of the gain stage circuit 206 as an input voltage.

In the example shown, the second buffer circuit 234 is arranged in a unity gain configuration, such as a diamond buffer configuration, e.g., a diamond source follower, and includes a top portion 238 and a bottom portion 240. The top portion 238 and the bottom portion 240 of the second buffer circuit 234 are arranged in a manner similar to the top portion 220 and the bottom portion 222 of the first buffer circuit 214 and, for brevity will not be described in detail again. The second buffer circuit 234 generates an output voltage Vopen for the dual-output amplifier circuit 200 at the second output node 204, where the second output voltage Vopen is equal to the first output voltage Vclose.

The dual-output amplifier circuit 200 includes a second buffer circuit 234 that sources current to a second resistive network (e.g., a load) that includes resistive elements R2A and R2B, where the second resistive network is coupled between the second output node 204 of the second buffer circuit 234 and a reference node. The second resistance proportional to the first resistance of the first resistive network, e.g., R1A=M*R2A, and R1B=M*R2B.

In the example shown in FIG. 2, the dual-output amplifier circuit 200 can include more than two buffer circuits. In particular, the second buffer circuit 234 can be coupled in parallel with one or more similar buffer circuits. For example, the second buffer circuit 234 can be coupled in parallel with third buffer circuit 242, where the third buffer circuit 242 is coupled with the first buffer circuit 214, where the second buffer circuit 234 and the third buffer circuit 242 share an input node, namely the input node 236. The input node 236 of the third buffer circuit is coupled with the output node 216 of the gain stage circuit 206 and is configured to receive the output voltage Vx of the gain stage circuit 206. In this configuration, the third buffer circuit 242 is configured to generate a portion of the second output voltage Vopen at the second output node 204.

The dual-output amplifier circuit 200 can include additional buffer circuits coupled in parallel with the second buffer circuit 234, such as a fourth buffer circuit 244 all the way to a Mth buffer circuit 246. These multiple buffer circuits coupled in parallel provide scaling, e.g., 10 buffer circuits, 10 resistive networks, coupled in parallel. The multiple buffer circuits can increase the drive or current capability of the dual-output amplifier circuit 200.

The first buffer circuit 214 includes transistors MN1A, MN1B, MP1A, MP1B and the bias currents. The second buffer circuit 234 includes transistors MN2A, MN2B, MP2A, MP2B and the bias currents. The second buffer circuit 234 can have M buffer circuits in parallel such that the second buffer circuit 234 is M times larger than the first buffer circuit 214 for better driving capability (M could be 1).

The second buffer circuit 234 drives equivalent resistive load R2A and R2B, which is M times less than the resistive load R1A and R1B of the first buffer circuit 214. The first buffer and second buffer have the same DC bias condition: same input voltage and equivalent resistive load. Therefore, the output voltage Vopen of the second buffer circuit 234 (and the dual-output amplifier circuit 200) equals the voltage Vclose when the voltage Vopen drives a capacitive load: Vopen=Vclose=(1+R1A/R1B)*Vin.

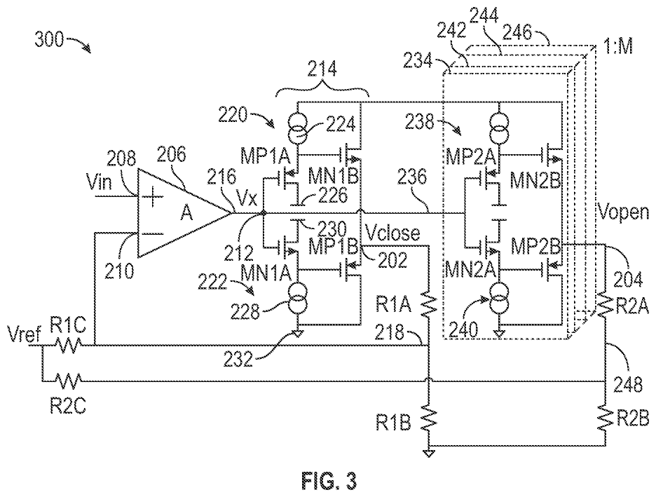

FIG. 3 is another example of an approach to a dual-output amplifier circuit in accordance with various techniques this disclosure. The dual-output amplifier circuit 300 of FIG. 3 is similar to the dual-output amplifier circuit 200 of FIG. 2 and, for brevity, similar features will not be described in detail again.

In addition to the features described above with respect to FIG. 2, the dual-output amplifier circuit 300 of FIG. 3 includes a third resistive network that includes resistive elements R1C and R2C. The third resistive network is coupled to the inverting input node 210 of the gain stage circuit 206 and configured to receive a reference voltage Vref. The third resistive network add a DC offset to adjust the output voltage Vopen and thus provide a level shifting function.

The second buffer circuit 234 drives equivalent resistive load R2A, R2B, and R2C, which is M times less than the resistive load R1A, R1B, and R1C, of the first buffer circuit 214. The first buffer and second buffer have the same DC bias condition: same input voltage and equivalent resistive load. Therefore, the output voltage Vopen of the second buffer circuit 234 (and the dual-output amplifier circuit 200) equals the voltage Vclose when the voltage Vopen drives a capacitive load: Vopen=Vclose=(1+R1A/((R1B*R1C)/(R1B+R1C)))*Vin−(R1A/R1C)*Vref.

### Various Notes

Each of the non-limiting claims or examples described herein may stand on its own, or may be combined in various permutations or combinations with one or more of the other examples.

The above detailed description includes references to the accompanying drawings, which form a part of the detailed description. The drawings show, by way of illustration, specific embodiments in which the invention may be practiced. These embodiments are also referred to herein as “examples.” Such examples may include elements in addition to those shown or described. However, the present inventors also contemplate examples in which only those elements shown or described are provided. Moreover, the present inventors also contemplate examples using any combination or permutation of those elements shown or described (or one or more claims thereof), either with respect to a particular example (or one or more claims thereof), or with respect to other examples (or one or more claims thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Method examples described herein may be machine or computer-implemented at least in part. Some examples may include a computer-readable medium or machine-readable medium encoded with instructions operable to configure an electronic device to perform methods as described in the above examples. An implementation of such methods may include code, such as microcode, assembly language code, a higher-level language code, or the like. Such code may include computer readable instructions for performing various methods. The code may form portions of computer program products. Further, in an example, the code may be tangibly stored on one or more volatile, non-transitory, or non-volatile tangible computer-readable media, such as during execution or at other times. Examples of these tangible computer-readable media may include, but are not limited to, hard disks, removable magnetic disks, removable optical disks (e.g., compact discs and digital video discs), magnetic cassettes, memory cards or sticks, random access memories (RAMs), read only memories (ROMs), and the like.

The above description is intended to be illustrative, and not restrictive. For example, the above-described examples (or one or more claims thereof) may be used in combination with each other. Other embodiments may be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments may be combined with each other in various combinations or permutations. The scope of the invention should be determined with reference to the appended claims, along with the full scope of equivalents to which such claims are entitled.

What is claimed is:

1. A dual-output amplifier circuit having a first output node and a second output node, the dual-output amplifier circuit comprising:
a gain stage circuit having a non-inverting input node and an inverting input node, wherein the non-inverting input node is configured to receive an input voltage;
a first buffer circuit coupled with the gain stage circuit, wherein an input node of the first buffer circuit is coupled with an output node of the gain stage circuit and is configured to receive an output voltage of the gain stage circuit, and wherein the first buffer circuit is configured to generate a first output voltage at the first output node;
a first resistive network coupled between the first output node of the first buffer circuit and the inverting input node of the gain stage circuit, wherein the first resistive network has a first resistance;
a second buffer circuit coupled with the first buffer circuit, wherein an input node of the second buffer circuit is coupled with the output node of the gain stage circuit and is configured to receive the output voltage of the gain stage circuit, and wherein the second buffer circuit is configured to generate a second output voltage at the second output node; and
a second resistive network coupled between the second output node of the second buffer circuit and a reference node, wherein the second resistive network has a second resistance proportional to the first resistance,
wherein the second output voltage is equal to the first output voltage.

2. The dual-output amplifier circuit of claim 1, comprising:
a third buffer circuit coupled in parallel with the second buffer circuit, wherein the third buffer circuit is coupled with the first buffer circuit, wherein an input node of the third buffer circuit is coupled with the output node of the gain stage circuit and is configured to receive the output voltage of the gain stage circuit, and wherein the third buffer circuit is configured to generate a portion of the second output voltage at the second output node.

3. The dual-output amplifier circuit of claim 1, comprising:
a third resistive network configured to adjust a level of the second output voltage.

4. The dual-output amplifier circuit of claim 3, wherein the third resistive network is coupled to the inverting input of the gain stage circuit and configured to receive a reference voltage.

5. The dual-output amplifier circuit of claim 3, comprising:
a third buffer circuit coupled in parallel with the second buffer circuit, wherein the third buffer circuit is coupled with the first buffer circuit, wherein an input node of the third buffer circuit is coupled with the output node of the gain stage circuit and is configured to receive the output voltage of the gain stage circuit, and wherein the third buffer circuit is configured to generate a portion of the second output signal at the second output node.

6. The dual-output amplifier circuit of claim 1, wherein the first resistive network includes a first resistive element and a second resistive element, wherein the first resistive element and the second resistive element are arranged in a voltage divider configuration; and
wherein the second resistive network includes a third resistive element and a fourth resistive element, wherein the third resistive element and the fourth resistive element are arranged in a voltage divider configuration.

7. The dual-output amplifier circuit of claim 1, wherein the first buffer circuit and the second buffer circuit are each arranged in a unity gain configuration.

8. The dual-output amplifier circuit of claim 1, wherein the first buffer circuit and the second buffer circuit are each arranged in a diamond buffer configuration.

9. The dual-output amplifier circuit of claim 1, wherein the first buffer circuit and the second buffer circuit include field-effect transistors.

10. A dual-output amplifier circuit having a first output node and a second output node, the dual-output amplifier circuit comprising:
a gain stage circuit having a non-inverting input node and an inverting input node, wherein the non-inverting input node is configured to receive an input voltage;
a first buffer circuit coupled with the gain stage circuit, wherein an input node of the first buffer circuit is coupled with an output node of the gain stage circuit and is configured to receive an output voltage of the gain stage circuit, and wherein the first buffer circuit is configured to generate a first output voltage at the first output node;
a first resistive network coupled between the first output node of the first buffer circuit and the inverting input node of the gain stage circuit, wherein the first resistive network has a first resistance;
a second buffer circuit coupled with the first buffer circuit, wherein an input node of the second buffer circuit is coupled with the output node of the gain stage circuit and is configured to receive the output voltage of the gain stage circuit, and wherein the second buffer circuit is configured to generate a second output voltage at the second output node; and
a second resistive network coupled between the second output node of the second buffer circuit and a reference node, wherein the second resistive network has a second resistance proportional to the first resistance,
wherein the second output voltage is equal to the first output voltage; and
a third buffer circuit coupled in parallel with the second buffer circuit, wherein the third buffer circuit is coupled with the first buffer circuit, wherein an input node of the third buffer circuit is coupled with the output node of the gain stage circuit and is configured to receive the output voltage of the gain stage circuit, and wherein the third buffer circuit is configured to generate a portion of the second output voltage at the second output node.

11. The dual-output amplifier circuit of claim 10, comprising:
a third resistive network configured to adjust a level of the second output voltage.

12. The dual-output amplifier circuit of claim 11, wherein the third resistive network is coupled to the inverting input of the gain stage circuit and configured to receive a reference voltage.

13. The dual-output amplifier circuit of claim 10, wherein the first resistive network includes a first resistive element and a second resistive element, wherein the first resistive element and the second resistive element are arranged in a voltage divider configuration; and
wherein the second resistive network includes a third resistive element and a fourth resistive element, wherein the third resistive element and the fourth resistive element are arranged in a voltage divider configuration.

14. The dual-output amplifier circuit of claim 10, wherein the first buffer circuit and the second buffer circuit are each arranged in a unity gain configuration.

15. The dual-output amplifier circuit of claim 10, wherein the first buffer circuit and the second buffer circuit are each arranged in a diamond buffer configuration.

16. A dual-output amplifier circuit having a first output node and a second output node, the dual-output amplifier circuit comprising:
a gain stage circuit having a non-inverting input node and an inverting input node, wherein the non-inverting input node is configured to receive an input voltage;
a first buffer circuit coupled with the gain stage circuit, wherein an input node of the first buffer circuit is coupled with an output node of the gain stage circuit and is configured to receive an output voltage of the gain stage circuit, and wherein the first buffer circuit is configured to generate a first output voltage at the first output node;
a first resistive network coupled between the first output node of the first buffer circuit and the inverting input node of the gain stage circuit, wherein the first resistive network has a first resistance;
a second buffer circuit coupled with the first buffer circuit, wherein an input node of the second buffer circuit is coupled with the output node of the gain stage circuit and is configured to receive the output voltage of the gain stage circuit, and wherein the second buffer circuit is configured to generate a second output voltage at the second output node; and
a second resistive network coupled between the second output node of the second buffer circuit and a reference node, wherein the second resistive network has a second resistance proportional to the first resistance,
wherein the second output voltage is equal to the first output voltage;
a third buffer circuit coupled in parallel with the second buffer circuit, wherein the third buffer circuit is coupled with the first buffer circuit, wherein an input node of the third buffer circuit is coupled with the output node of the gain stage circuit and is configured to receive the output voltage of the gain stage circuit, and wherein the third buffer circuit is configured to generate a portion of the second output voltage at the second output node; and
a third resistive network configured to adjust a level of the second output voltage.

17. The dual-output amplifier circuit of claim 16, wherein the third resistive network is coupled to the inverting input of the gain stage circuit and configured to receive a reference voltage.

18. The dual-output amplifier circuit of claim 16, wherein the first resistive network includes a first resistive element and a second resistive element, wherein the first resistive element and the second resistive element are arranged in a voltage divider configuration; and
wherein the second resistive network includes a third resistive element and a fourth resistive element, wherein the third resistive element and the fourth resistive element are arranged in a voltage divider configuration.

19. The dual-output amplifier circuit of claim 16, wherein the first buffer circuit and the second buffer circuit are each arranged in a unity gain configuration.

20. The dual-output amplifier circuit of claim 16, wherein the first buffer circuit and the second buffer circuit are each arranged in a diamond buffer configuration.
